(19) United States
(12) Patent Application Publication
(10) Pub. No.: US 2010/0065116 A1
(43) Pub. Date: Mar. 18, 2010

(54) Impact Resistant Thin-Glass Solar Modules

(76) Inventors: Robert Stancel, Los Altos, CA (US); Paul Adriani, Palo Alto, CA (US); Louis Basel, San Jose, CA (US); Joseph Jalbert, San Jose, CA (US)

Correspondence Address: Director of IP, 5521 Hellyer Avenue, San Jose, CA, 95138, US

(21) Appl. No.: 12/541,149

(22) Filed: Aug. 13, 2009

Related U.S. Application Data
(60) Provisional application No. 61/088,702, filed on Aug. 13, 2008.

(51) Int. Cl. H01L 31/00

(52) U.S. Cl. 136/256

(57) ABSTRACT

Methods and devices are provided for solar module designs. In one embodiment, a durable thin glass solar module is provided. The system comprises of a photovoltaic module with at least one layer comprised of a thin glass layer with protection which protects against microcracks (radial and concentric) which may form during hail impacts.

### CROSS-REFERENCE TO RELATED APPLICATION

This application claims priority to U.S. Provisional Patent Application No. 61/088,702 filed Aug. 13, 2008 and fully incorporated herein by reference for all purposes.

### FIELD OF THE INVENTION

This invention relates generally to photovoltaic devices, and more specifically, to more durable solar cell modules.

### BACKGROUND OF THE INVENTION

Solar cells and solar cell modules convert sunlight into electricity. Traditional solar cell modules are typically comprised of polycrystalline and/or monocrystalline silicon solar cells mounted on a support with a rigid glass top layer to provide environmental and structural protection to the underlying silicon based cells. This package is then typically mounted in a rigid aluminum or metal frame that supports the glass and provides attachment points for securing the solar module to the installation site. A host of other materials are also included to make the solar module functional. This may include junction boxes, bypass diodes, sealants, and/or multi-contact connectors used to complete the module and allow for electrical connection to other solar modules and/or electrical devices. Certainly, the use of traditional silicon solar cells with conventional module packaging is a safe, conservative choice based on well understood technology.

Drawbacks associated with traditional solar module package designs, however, have limited the ability to install large numbers of solar modules in a cost-effective manner. This is particularly true for large scale deployments where it is desirable to have large numbers of solar modules setup in a defined, dedicated area. Traditional solar module packaging comes with a great deal of redundancy and excess equipment cost. For example, a recent installation of conventional solar modules in Pocking, Germany deployed 57,912 monocrystalline and polycrystalline-based solar modules. This meant that there were also 57,912 junction boxes, 57,912 aluminum frames, untold meters of cablings, and numerous other components. These traditional module designs inherit a large number of legacy parts that hamper the ability of installers to rapidly and cost-efficiently deploy solar modules at a large scale.

Additionally, the ability to create larger solar modules and/or solar modules using less expensive material have also been limited due to the load requirements that solar modules meet to gain certification. The ability to make such modules is restricted by these load requirements.

Although subsidies and incentives have created some large solar-based electric power installations, the potential for greater numbers of these large solar-based electric power installations has not been fully realized. There remains substantial improvement that can be made to photovoltaic cells and photovoltaic modules that can greatly increase their ease of installation, and create much greater market penetration and commercial adoption of such products.

### SUMMARY OF THE INVENTION

Embodiments of the present invention address at least some of the drawbacks set forth above. The present invention provides for the improved solar module designs that reduce manufacturing costs and redundant parts in each module. These improved module designs are well suited for rapid installation. It should be understood that at least some embodiments of the present invention may be applicable to any type of solar cell, whether they are rigid or flexible in nature or the type of material used in the absorber layer. Embodiments of the present invention may be adaptable for roll-to-roll and/or batch manufacturing processes. At least some of these and other objectives described herein will be met by various embodiments of the present invention.

In one embodiment of the present invention, a photovoltaic module is provided comprising a thin glass layer with a thickness of about 0.5 mm or less; a support layer beneath the thin glass layer that has sufficient compliance to prevent radial cracking of the thin glass layer and has sufficient indentation hardness to prevent concentric cracking of the thin glass layer from 227 g metal ball strikes dropped from a height of 1 m; and a plurality of solar cells are between the thin glass layer and the support layer.

It should be understood that any of the embodiments herein may be configured to have one or more of the following features. By way of nonlimiting example, the thin glass layer has a thickness of about 0.40 mm or less. Optionally, the thin glass layer has a thickness of about 0.30 mm or less. Optionally, the thin glass layer has a thickness of 0.25 mm or less. Optionally, the thin glass layer has a thickness of 0.17 mm or less. Optionally, the thin glass layer has a thickness of 0.15 mm or less. Optionally, the support layer comprises a fiber reinforced plastic. Optionally, the support layer comprises an epoxy based woven fiber material. Optionally, the support layer has a thickness that provides a bending radius less than a breaking radius for a reverse static load of 2400 pa. Optionally, the support layer has a thickness between about 700 microns to about 1000 microns. Optionally, the support layer has a thickness between about 600 microns to about 1100 microns. Optionally, the support layer has a thickness between about 750 microns. Optionally, the support layer has a Flexural Modulus of Elasticity (PSI) between about 2,650,000 to about 2,750,000. Optionally, the support layer has a Flexural Modulus of Elasticity (PSI) between about 2,690,000 to about 2,710,000. Optionally, the support layer has a Flexural Modulus of Elasticity (PSI) between about 2,650,000 to about 2,750,000 with a thickness between about 700 microns to about 1100 microns. Optionally, the support layer has a Flexural Modulus of Elasticity (PSI) between about 2,700,000 with a thickness between about 700 microns to about 1000 microns. Optionally, the support layer comprises of a woven glass fiber material with epoxy. Optionally, the module further comprises an impact spreading layer above the thin glass layer. Optionally, the impact spreading layer comprises of an opaque polymer material removably adhered to the thin glass layer. Optionally, the support layer comprises a mechanically stable glass cloth epoxy resin, laminated under high pressure.

A further understanding of the nature and advantages of the invention will become apparent by reference to the remaining portions of the specification and drawings.

### BRIEF DESCRIPTION OF THE DRAWINGS

FIG. 1A is an exploded perspective view of a module according to one embodiment of the present invention.

FIG. 1B is a side view of a module of FIG. 1A.

FIG. 1C is an exploded perspective view of a module according to another embodiment of the present invention.

FIG. 2 is a side view of a module of FIG. 1C.

FIGS. 3 through 7 show cross-sectional views of various embodiments of the present invention.

FIGS. 8-11 show perspective views of embodiments of the present invention with perimeter protection.

FIGS. 12 and 13 show two different glass fracture patterns.

FIG. 14 shows a graphic of load distribution versus energy absorption.

FIGS. 15 and 16 show module layers of various embodiments of the present invention.

FIGS. 17 and 18 show the module in various bending modes.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for an anti-reflective film, this means that the anti-reflective film feature may or may not be present, and, thus, the description includes both structures wherein a device possesses the anti-reflective film feature and structures wherein the anti-reflective film feature is not present.

### Photovoltaic Module

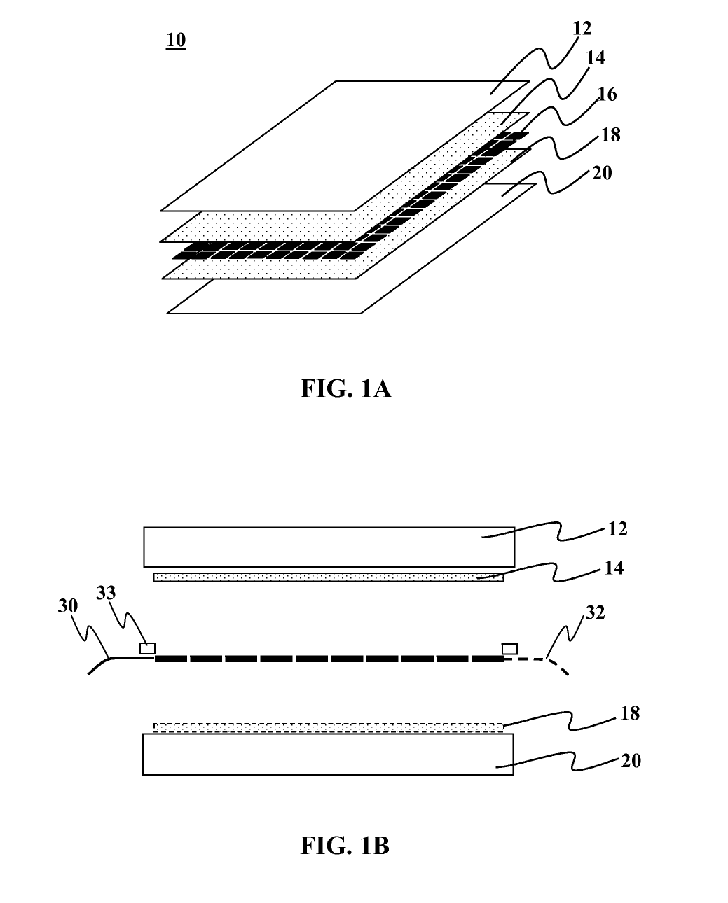

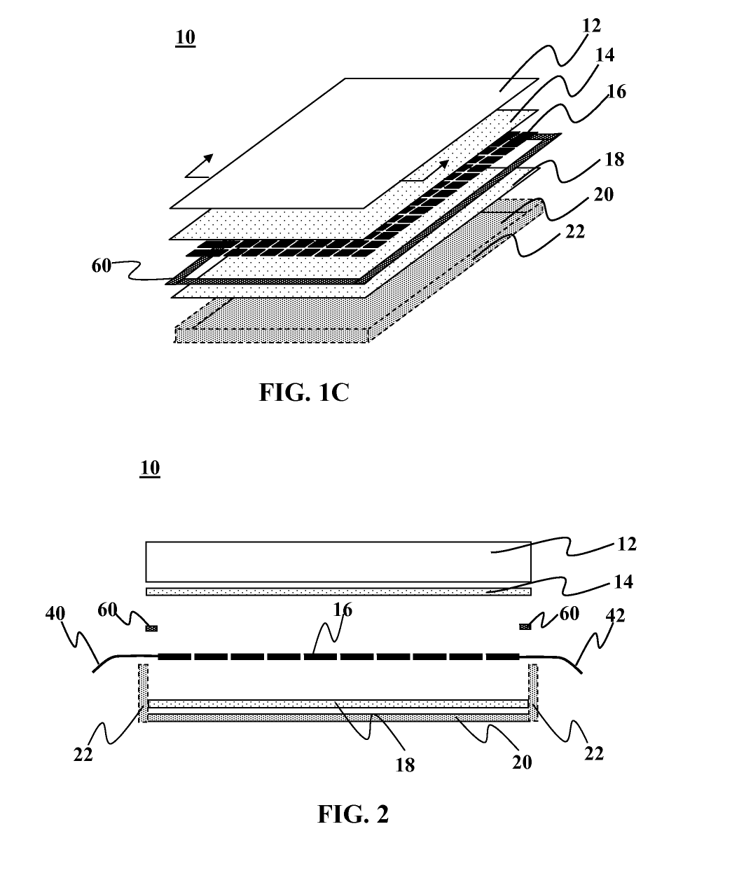

Referring now to FIG. 1A one embodiment of a module 10 according to the present invention will now be described. Traditional module packaging and system components were developed in the context of legacy cell technology and cost economics, which had previously led to very different module and system design assumptions than those suited for increased product adoption and market penetration. The cost structure of solar modules includes both factors that scale with area and factors that are fixed per module. Module 10 is designed to minimize fixed cost per module and decrease the incremental cost of having more modules while maintaining substantially equivalent qualities in power conversion and module durability. In this present embodiment, the module 10 may include improvements to the backsheet, frame modifications, thickness modifications, and electrical connection modifications.

FIG. 1A shows that the present embodiment of module 10 may include a rigid transparent upper layer 12 followed by a pottant layer 14 and a plurality of solar cells 16. Below the layer of solar cells 16, there may be another pottant layer 18 of similar material to that found in pottant layer 14. Beneath the pottant layer 18 may be a layer of backsheet material 20. The transparent upper layer 12 may provide structural support and/or act as a protective barrier. By way of nonlimiting example, the transparent upper layer 12 may be a glass layer comprised of materials such as conventional glass, solar glass, high-light transmission glass with low iron content, standard light transmission glass with standard iron content, anti-glare finish glass, glass with a stippled surface, fully tempered glass, heat-strengthened glass, annealed glass, or combinations thereof. By way of example and not limitation, the total thickness of the glass or multi-layer glass may be in the range of about 0.05 mm to about 13.0 mm, optionally from about 2.8 mm to about 12.0 mm. Some embodiments may have even thinner glass, such as from 01-1.0 mm. In one embodiment, the top layer 12 has a thickness of about 3.2 mm. In another embodiment, the backlayer 20 has a thickness of about 2.0 mm. As a nonlimiting example, the pottant layer 14 may be any of a variety of pottant materials such as but not limited to Tefzel®, ethyl vinyl acetate (EVA), polyvinyl butyral (PVB), ionomer, silicone, thermoplastic polyurethane (TPU), thermoplastic elastomer polyolefin (TPO), tetrafluoroethylene hexafluoropropylene vinylidene (THV), fluorinated ethylene-propylene (FEP), saturated rubber, butyl rubber, thermoplastic elastomer (TPE), flexibilized epoxy, epoxy, amorphous polyethylene terephthalate (PET), urethane acrylic, acrylic, other fluoroelastomers, other materials of similar qualities, or combinations thereof. Optionally, some embodiments may have more than two pottant layers. The thickness of a pottant layer may be in the range of about 10 microns to about 1000 microns, optionally between about 25 microns to about 500 microns, and optionally between about 50 to about 250 microns. Others may have only one pottant layer (either layer 14 or layer 16). In one embodiment, the pottant layer 14 is about 75 microns in cross-sectional thickness. In another embodiment, the pottant layer 14 is about 50 microns in cross-sectional thickness. In yet another embodiment, the pottant layer 14 is about 25 microns in cross-sectional thickness. In a still further embodiment, the pottant layer 14 is about 10 microns in cross-sectional thickness. The pottant layer 14 may be solution coated over the cells or optionally applied as a sheet that is laid over cells under the transparent module layer 12.

It should be understood that the simplified module 10 is not limited to any particular type of solar cell. The solar cells 16 may be silicon-based or non-silicon based solar cells. By way of nonlimiting example the solar cells 16 may have absorber layers comprised of silicon (monocrystalline or polycrystalline), amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), copper-indium-gallium-selenium (for CIGS solar cells), CdSe, CdTe, Cu(In,Ga)(S,Se)₂, Cu(In,Ga,Al)(S,Se,Te)₂, and/or combinations of the above, where the active materials are present in any of several forms including but not limited to bulk materials, micro-particles, nano-particles, or quantum dots. Advantageously, thin-film solar cells have a substantially reduced thickness as compared to silicon-based cells. The decreased thickness and concurrent reduction in weight allows thin-film cells to form modules that are significantly thinner than silicon-based cells without substantial reduction in structural integrity (for modules of similar design).

The pottant layer 18 may be any of a variety of pottant materials such as but not limited to EVA, Tefzel®, PVB, ionomer, silicone, TPU, TPO, THV, FEP, saturated rubber, butyl rubber, TPE, flexibilized epoxy, epoxy, amorphous PET, urethane acrylic, acrylic, other fluoroelastomers, other materials of similar qualities, or combinations thereof as previously described for FIG. 1. The pottant layer 18 may be the same or different from the pottant layer 14. Further details about the pottant and other protective layers can be found in commonly assigned, co-pending U.S. patent application Ser. No. 11/462,359 (Attorney Docket No. NSL-090) filed Aug. 3, 2006 and fully incorporated herein by reference for all purposes. Further details on a heat sink coupled to the module can be found in commonly assigned, co-pending U.S. patent application Ser. No. 11/465,783 (Attorney Docket No. NSL-089) filed Aug. 18, 2006 and fully incorporated herein by reference for all purposes.

FIG. 1B shows a cross-sectional view of the module of FIG. 1A By way of nonlimiting example, the thicknesses of backsheet 20 may be in the range of about 10 microns to about 1000 microns, optionally about 20 microns to about 500 microns, or optionally about 25 to about 250 microns. Again, as seen for FIG. 1B this embodiment of module 10 is a frameless module without a central junction box. The present embodiment may use a simplified backsheet 20 that provides protective qualities to the underside of the module 10. As seen in FIG. 1A the module may use a rigid backsheet 20 comprised of a material such as but not limited to annealed glass, heat strengthened glass, tempered glass, flow glass, cast glass, or similar materials as previously mentioned. The rigid backsheet 20 may be made of the same or different glass used to form the upper transparent module layer 12. Optionally, in such a configuration, the top sheet 12 may be a flexible top sheet such as that set forth in U.S. patent application Ser. No. 11/460,617 filed Jun. 26, 2006 and fully incorporated herein by reference for all purposes. In one embodiment, electrical connectors 30 and 32 may be used to electrically couple cells to other modules or devices outside the module 10. A moisture barrier material 33 may also be included along a portion or all of the perimeter of the module.

### Foil Back Layer Photovoltaic Module

Referring now to FIG. 1C one embodiment of a module 10 according to the present invention will now be described. FIG. 1C shows that the present embodiment of module 10 may include a transparent module front layer 12 followed by a pottant layer 14, a plurality of solar cells 16, optionally a second pottant layer 18, and a module back layer 20. By way of nonlimiting example, the transparent front layer 12 may be a substantially transparent glass plate that provides structural support and acts as a protective barrier. The pottant layers 14 and 18 may be of the same or different pottant materials. Advantageously, the module back layer 20 in the present embodiment may be a conductive metal foil that provides a low cost, light weight backside protective barrier for the solar cells 16 in the module 10. This type of module back layer eliminates the traditional back layer used in conventional modules which are either heavy such as glass, expensive such as Tedlar®/Aluminum/polyester/Tedlar® (TAPT) laminate, or both. A conductive foil module back layer 20 in conjunction with only one glass front layer 12 creates a significantly lighter module while retaining a robust design and simplifying module manufacturing. This results in significantly lower module cost as compared to conventional glass-glass, glass-film-framed, or glass-film-unframed modules.

Referring still to FIG. 1C the various components of module 10 will be described in further detail. As seen in this embodiment, the module 10 may include a transparent front layer 12 that may be a glass plate comprised of one or more materials such as, but not limited to, conventional glass, float glass, solar glass, high-light transmission glass with low iron content, standard light transmission glass with standard iron content, anti-glare finish glass, anti-reflective finish, glass with a stippled surface, glass with a pyramidal surface, glass with textured surface, fully tempered glass, heat-strengthened glass, annealed glass, or combinations thereof. Module front layer 12 is not limited to any particular shape, and it may be rectangular, square, oval, circular, hexagonal, L-shaped, polygonal, other shapes, or combinations of any of the foregoing. The total thickness of the glass or multi-layer glass for layer 12 may be in the range of about 0.1 mm to about 13.0 mm, optionally from about 2.8 mm to about 12.0 mm. In one embodiment, glass of 1.0 mm or less may be used. In one embodiment, glass of 0.9 mm or less may be used. In one embodiment, glass of 0.8 mm or less may be used. In one embodiment, glass of 0.7 mm or less may be used. In one embodiment, glass of 0.6 mm or less may be used. In one embodiment, glass of 0.5 mm or less may be used. In one embodiment, glass of 0.4 mm or less may be used. In one embodiment, glass of 0.3 mm or less may be used. In one embodiment, glass of 0.2 mm or less may be used. In one embodiment, glass of 0.1 mm or less may be used. Thin glass may be selected to match the coefficient of thermal expansion in the other layers used in the module stack. In one embodiment, glass of 2.0 mm to about 1.0 may be used. In one embodiment, glass of 1.0 mm or less may be used. In another embodiment, the layer 12 has a total thickness of about 2.0 mm to 6.0 mm. In another embodiment, the layer 12 has a total thickness of about 3.0 mm to 5.0 mm. In yet another embodiment, the front layer 12 has a thickness of about 4.0 mm. It should be understood that in some embodiments, the transparent front layer 12 may be made of a non-glass material that provides a transparent rigid plate. Optionally, the front layer 12 whether it is glass or non-glass is substantially transparent in a spectral range from about 400 nm to about 1100 nm. Optionally, some embodiments of the present invention may have surface treatments applied to the glass such as but not limited to filters, anti-reflective layers, surface roughness, protective layers, moisture barriers, or the like. Although not limited to the following, the top layer is typically glass except those with anti-reflective finish which consists of one or more thin film layers applied to the glass.

Referring still to the embodiment of FIG. 1C the pottant layer 14 in module 10 may be any of a variety of pottant materials such as, but not limited to, ethyl vinyl acetate (EVA), polyvinyl butyral (PVB), ionomer, silicone, thermoplastic polyurethane (TPU), thermoplastic polyolefin (TPO), tetrafluoroethylene hexafluoropropylene vinylidene (THV), fluorinated ethylene-propylene (FEP), Tefzel® (ETFE), saturated rubber, butyl rubber, thermoplastic elastomer (TPE), flexibilized epoxy, epoxy, amorphous polyethylene terephthalate (PET), urethane acrylic, acrylic, other fluoroelastomers, other materials of similar qualities, or combinations thereof. The module 10 may have one or more pottant layers. Optionally, some embodiments of module 10 may have two or more pottant layers. The thickness of each pottant layer may be in the range of about 10 microns to about 1000 microns, optionally between about 25 microns to about 500 microns, and optionally between about 50 to about 250 microns. The module may use a layer of pottant that is thinner than about 200 microns. In one embodiment, the pottant layer 14 is about 100 microns in cross-sectional thickness. In another embodiment, the pottant layer 14 is about 50 microns in cross-sectional thickness. In yet another embodiment, the pottant layer 14 is about 25 microns in cross-sectional thickness.

In some embodiments where the module has two pottant layers, the second pottant layer 18 is about 100 microns in cross-sectional thickness. Optionally, the second pottant layer 18 is about 400 microns in cross-sectional thickness. Again, the thickness of the second pottant layer may be between the range of about 10 microns to about 1000 microns, optionally between about 25 microns to about 500 microns, and optionally between about 50 to about 250 microns. The pottant layers 14 and 18 may be of the same or different thicknesses. They may be of the same or different pottant material. Although not limited to the following, the pottant layers 14 or 18 may be solution coated over the cells or optionally applied as a sheet that is laid over cells under the transparent module layer 12. Further details about the pottant and other protective layers can be found in commonly assigned, co-pending U.S. patent application Ser. No. 11/462,359 (Attorney Docket No. NSL-090) filed Aug. 3, 2006 and fully incorporated herein by reference for all purposes. It should be understood the highly heat transmitting pottant materials may also be used and further details on such materials can be found in commonly assigned, co-pending U.S. patent application Ser. No. 11/465,783 (Attorney Docket No. NSL-089) filed Aug. 18, 2006 and fully incorporated herein by reference for all purposes.

It should be understood that the solar module 10 and any of the solar modules herein are not limited to any particular type of solar cell. The solar cells 16 may be silicon-based or non-silicon based solar cells. By way of nonlimiting example, the solar cells 16 may have absorber layers comprised of silicon (monocrystalline or polycrystalline), amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), copper-indium-gallium-selenium (for CIGS solar cells), CdSe, CdTe, Cu(In,Ga)(S,Se)₂, Cu(In,Ga,Al)(S,Se,Te)₂, and/or combinations of the above, where the active materials are present in any of several forms including but not limited to bulk materials, micro-particles, nano-particles, or quantum dots. Advantageously, thin-film solar cells have a substantially reduced thickness as compared to silicon-based cells. The decreased thickness and concurrent reduction in weight allows thin-film cells to form modules that are significantly thinner than silicon-based cells without substantial reduction in structural integrity (for modules of similar design). The solar cells 16 may have various cross-sectional thicknesses. In one embodiment, it may be about 300 microns in cross-sectional thickness. Other cells may have thicknesses in the range of about 30 microns to about 1000 microns or optionally, 50 microns to about 500 microns.

Referring still to FIG. 1C to provide a reduced material cost and simplified module design, a foil module back layer 20 may be used. Although not limited to the following, the foil may be a bare foil that forms the backside surface of the module without additional coatings on the expose foil surface. The module back layer 20 may be a conductive foil comprised of one or more of the following materials: aluminum, zinc-aluminum alloy coated steel (such as Galvalume®), Corrtan® steel (a controlled corrosion steel with an adherent oxide), tin-coated steel, chromium coated steel, nickel-coated steel, stainless steel, galvanized steel, copper, conductive-paint coated metal foil such as weather resistant polymer containing carbon fiber, graphite, carbon black, nickel fiber, nickel particles, combinations thereof, or their alloys. In one embodiment, the low cost module back layer 20 is an externally exposed aluminum foil. Although not limited to the following, the cross-sectional thickness of the aluminum foil may be between about 10 μm to about 1000 μm, optionally between about 50 μm and about 500 μm, or optionally between about 50 μm and about 200 μm. Such thicknesses may be desirable to provide for pinhole-free, cut-resistant, wrinkle-resistant performance. The use of a low cost, lightweight, corrosion resistant material is desirable to reduce cost and simplify module design.

As seen in FIG. 2, the module back layer 20 may also be of various sizes and shapes and is not limited to being a rectangular sheet of material in only one plane of the module. FIG. 2 shows a cross-sectional view of the module of FIG. 1. By way of nonlimiting example, some embodiments of the module back layer 20 may be sized to cover not only the back of the module 10 but also include portions 22 (shown in phantom) which may extend to cover one or more of the side edges of the module 10. The use of vertical portions 22 of module back layer 20 may improve the moisture barrier quality of the module 10 as it provides a continuous length of material that covers both the back of module and possible sideways moisture entry points from between the module front layer 12 and the module back layer 20. As the portions 22 are continuous with the layer 20, this reduces the number seams or seals that would exist if these elements were separate pieces. Additional details of the fold seal formed along the edges of module 10 are described in FIG. 4.

Referring still to FIG. 2, the present embodiment of module 10 shows a frameless module without a central junction box with electrical ribbons 40 and 42 for electrically coupling adjacent modules together. Although not limited to the following, the electrical lead wires/ribbons 40 and 42 may extend outward from between the module front layer 12 and the module back layer 20. These ribbons 40 and 42 are designed to exit along the sides of the module, between the various layers 12 and 20, rather than through them. This simplifies the issue of having to form openings in back layer or the front layer which may be an issue if the openings are improperly formed during such procedures. The electrical lead 42 may extend from one side of the cell 16 (either top or bottom) and not necessarily from the middle. The ribbon 40 may connect to a first cell in a series of electrically coupled cells and the ribbon 42 may connect to the last cell in the series of electrically coupled cells. The wires or ribbons 40 and 42 may optionally have a coating or layer to electrically insulate themselves from the backsheet 20. Optionally in some alternative embodiments, the wires or ribbons 40 and 42 may exit through an opening in the conductive metal foil layer. FIGS. 1 and 2 also show that a moisture barrier 60 may be positioned around the perimeter of the module. This barrier 60 may be at least partially enclosed by the module front layer 12 and module back layer 20. The barrier 60 may be comprised of a seal material alone or a seal material loaded with desiccant.

In some embodiments, a moisture barrier 60 may be included to prevent moisture entry into the interior of the module. The moisture barrier 60 may optionally extend around the entire perimeter of the module or only along select portion. In one embodiment, the moisture barrier 60 may be about 5 mm to about 20 mm in width (not thickness) around the edges of the module. In one embodiment, the moisture barrier 60 may be butyl rubber, a zeolyte material, or other barrier material as described herein and may optionally be loaded with desiccant to provide enhanced moisture barrier qualities.

### Module Voltage Withstand

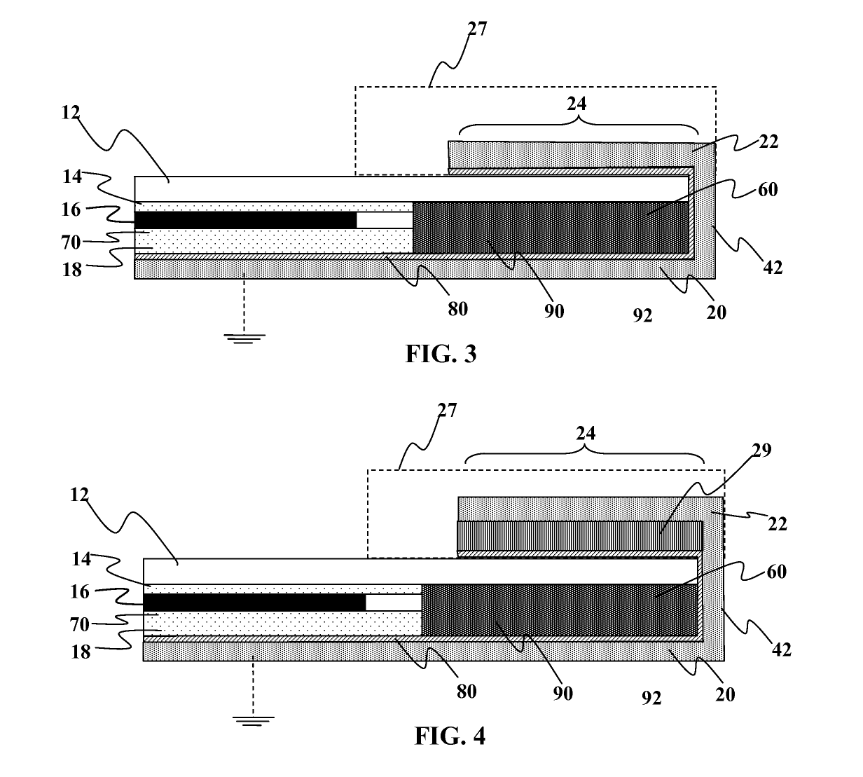

Referring now to FIG. 3, in some embodiments of the present invention, it is desirable that the nearest point of approach from the cells 16 to the module back layer 20 be sufficiently far and/or through sufficiently electrically insulating material to provide a high voltage withstand. Although not limited to the following, embodiments of present invention may use a pottant material that provides both encapsulating qualities and electrically insulating qualities to achieve the desired insulating quality. In one embodiment, the high voltage withstand between the cells 16 and the module back layer 20 is at least about 500V. Optionally, the high voltage withstand is at least about 1000V. Optionally, the high voltage withstand is at least about 2000V. Optionally, the high voltage withstand is at least about 3000V. Optionally, the high voltage withstand is at least about 4000V. Of course, some embodiments of modules operated in secure, limited access facilities may be designed without any particular voltage withstand (i.e. 500V or less) as the limited access nature allows only qualified personnel near the modules in conditions when it is safe to do so.

As seen in FIG. 3, to achieve the desired voltage withstand, various elements may be incorporated into the module. In one embodiment, spacers are used to maintain distance between the cells 16 to the foil 20. Two nonlimiting examples of suitable spacers include: 1) a spacer layer 70 of nonwoven or woven glass cloth with small mesh impregnated with one of the following: TPO, ionomer, TPU, EVA, or similar encapsulating pottant with thickness between 50 μm and 500 μm (thicker is higher voltage withstand) or 2) a stack of small mesh glass cloth (or thin, hard, temperature-resistant polymer film such as 25 μm of PET) on top of large mesh glass cloth 70 to separate the roles of high uniformity of spacing from high thickness of spacing, where the stack is impregnated with encapsulant of the type previously recited herein. In some embodiments, the spacer 70 has a thickness in the range of about 75 microns to about 150 microns. In some embodiments, the spacer 70 has a thickness in the range of about 50 microns to about 300 microns. In some embodiments, the spacer 70 has a thickness in the range of about 200 microns to about 500 microns. In some embodiments, the spacer layer 70 is about 100 microns in thickness. The pottant layer 18 may be designed to flow into the openings in glass cloth 70. Optionally, the hard spacer in layer 70 should be hard to ensure consistent spacing performance under pressure. The spacers are preferably temperature resistant to remain hard under peak lamination temperature which in one embodiment is about 150° C. and pressure of about 1 Atm (ca. 0.1 MPa). The number or distributed area of spacers may be enough to consistently space all the portions of the solar cell circuit from the module back layer 20.

As seen in FIG. 3, the thicknesses of pottant layers 14 and 18 may be asymmetric, with pottant layer 18 being thicker than upper pottant layer 14. This may be desirable to maintain a greater spacing between the cells 16 and back layer 20 to maximize the electrical insulation between these layers. It should also be understood that the material for pottant layer 18 may be selected to be electrically insulating. In some embodiments, the material in pottant layer 18 is more electrically insulating than the material used in the upper pottant layer 14. Optionally, the pottant layer 18 through its cross-sectional thickness and material quality provides about 500V high voltage withstand between the cell 16 and the outer, exposed surface of module back layer 20. In another embodiment, the pottant layer 18 provides about 1000V high voltage withstand between the cell 16 and the outer, exposed surface of module back layer 20. In another embodiment, the pottant layer 18 provides about 2000V high voltage withstand between the cell 16 and the outer, exposed surface of module back layer 20. In another embodiment, the pottant layer 18 provides about 3000V high voltage withstand between the cell 16 and the outer, exposed surface of module back layer 20. In yet another embodiment, the pottant layer 18 provides about 4000V high voltage withstand between the cell 16 and the outer, exposed surface of module back layer 20. In some other embodiments, it total combination of the pottant layer with spacer layer 70 that provides the above listed high voltage withstand. Material that is more voltage withstanding includes silicones, polyimides such as Kapton®, polyesters such as Mylar®, halogenated, aromatic, or polymeric materials. For insulation based on air spacing, an air spacing of 2 mm is used for 600V rating to 10 mm for 4000V rating. These are merely exemplary and nonlimiting.

Optionally, additional insulating material may be formed on the foil, such as but not limited to anodization. Optionally, other embodiments may use more electrically insulative pottant material. Any of the options may be used singly or in combination. In still other embodiments, it is the combination of all layers between the cell 16 and the outer, exposed surface of module back layer 20 that provides this high voltage withstand. The use of an electrically insulating pottant material for layer 18 optionally allows the layer 20 to be used without having to add additional insulating layers such as a layer of Tedlar® found in traditional module configurations that increase materials cost. The present invention may slightly thicken the aluminum foil while also eliminating, reduce, or “reduce-and-move” the polyester film also found in conventional module. Additionally, as seen in FIG. 3, there may be an electrically insulating material 41 optionally used with the electrical ribbon or wire 42. The insulating material 41 may be in the form of a sleeve completely surrounding the ribbon or wire 42. It may also be in any other form such as but not limited to a piece above, below, and/or around the electrical ribbon or wire 42 to electrically insulate it from the module back layer 20. In one embodiment, the electrically insulating material may be a polymer, butyl rubber, glass, an insulating fabric/weave, or other insulating material. The insulating feature may be used with any embodiments herein and is not limited to those embodiments where the metal foil is wrapped around the side of the module.

It should also be understood that for aesthetic reasons, the pottant layer 18 may contains pigment to provide the pottant layer 18 with a particular color. In one embodiment, the pottant layer 18 may be black in color. In another embodiment, the pottant layer 18 may be white in color.

### Fold Seal

Referring now to FIG. 4, it is seen that the foil layer 20 may also have a portion 24 that extends to a front side surface of the front layer 12. This improves the mechanical qualities of the bond between the foil layer 20 and the module 10 by having bonds on opposing surfaces of the module (i.e. on both the front surface and the back surface). This area 24 may also be useful in protecting modules made of thin glass (2.0 mm or less). This additional portion 24 also increases the path length that moisture would need to pass through if moisture were to try to enter between the foil layer 20 and front layer 12 to reach the cells 16 as indicated by arrows 26. In some embodiments, the portion 24 may be between 1-5 inches in width (although it is not limited to any particular width). In some embodiments, the portion 24 may be between 2-7 inches in width (although it is not limited to any particular width). In some embodiments, the portion 24 may be at least 10 inches in width (although it is not limited to any particular width). There may be sufficient space beneath the area 24 so that no cells are shaded. The cells maybe placed more toward the center, away from the perimeter of the module. Optionally, the overhang of portion 24 may be form a piece 120 that is separate from the backside foil. The foil 24 may be anodized or treated in other manners. In one embodiment, the length of section 24 may be of the same dimension as the width of underlying moisture barrier 60. The section 24 may be sized so as not to extend over any portion of the solar cells 16 so as to shade them or reduce their electrical output. In some embodiments, the length of section 24 may be between about 1 mm to about 20 mm, optionally between about 2 mm and about 15 mm. The optional edge folded version of the aluminum back layer 20 may provide for improved reliability. The optional folded edge of the aluminum back sheet can be adhered to the glass coversheet of the solar module with thin or thick adhesives, with or without desiccant additive, with or without glass adhesion promoter (typically silane-based). It can also be seen that the module back layer in FIG. 4 or any of the embodiments herein may be grounded. FIG. 4 also shows that an optional insulating material 43 may be used to prevent electrical contact with the metal foil. Some embodiments may use an insulating material 45 that is only above or below the wire or ribbon 42. In one embodiment, the electrically insulating material may be a polymer, butyl rubber, glass, an insulating fabric/weave, or other insulating material. The insulating feature or features may be used with any embodiments herein and is not limited to those embodiments where the metal foil is wrapped around the side of the module.

For the embodiments of FIGS. 3 and 4 which include an adhesive layer, the adhesive layer 80 may be included between the foil module layer 20 and the other elements of the module 10. This adhesive layer 80 is of particular use in adhering the foil module layer 20 to any hard smooth surface such as the surfaces of module front layer 12. The adhesive layer 80 may be comprised of one or more of the following: butyl rubber, silane primer, polyurethane, acrylic, saturated rubber, unsaturated rubber, thermoplastic elastomer (TPE), thermoplastic olefin, acrylic-based adhesive, urethane-based adhesive, EVA, PVB, TPU, ionomer, flexibilized epoxy, epoxy, or similar adhesives. Water vapor transmission rate (WVTR) of the adhesive is important in embodiments with moisture sensitive solar cells. Butyl rubber adhesive is one suitable adhesive type with low WVTR. The thickness of adhesive layer 80 may be in the range of about 10 to about 50 microns. In another embodiment, the adhesive layer 80 may be about 25 microns in thickness. The adhesive layer 80 may cover the entire surface of the foil layer 20 and other continuous portions of the foil such as section 22. Optionally, the adhesive layer 80 covers select areas of the back layer 20 such as but not limited to areas of contact between the back layer 20 and the front module layer 12.

In manufacturing a module with a fold seal, it should understood that for embodiments with edge exiting electrical connectors, the openings to allow an edge exiting connector to extend from the module may be formed before the layer 20 is coupled to the module, after a portion of the layer 20 is coupled to the module, or after the layer 20 is coupled and the fold seal adhered.

### Moisture Barrier

As seen in FIG. 3, for any of the embodiments herein, a moisture barrier 60 may be used with the module 10 to improve the barrier seal along the edge perimeter of the module. The moisture barrier 60 may be positioned along the entire or substantially entire perimeter of the module 10. The barrier 60 may be sandwiched between the module layers to provide weatherproofing and moisture barrier qualities to the module. In some embodiments, the barrier is between the upper and lower layers 10 and 20. In other embodiments, it may be sandwiched between one or more of the pottant layers. In one embodiment, the moisture barrier 60 may be about 5 mm to about 20 mm in width (not thickness) around the edges of the module. The barrier 60 may be comprised of one or more of the following materials such as but not limited to desiccant loaded versions of EVA, Tefzel®, PVB, ionomer, silicone, TPU, TPO, THV, FEP, saturated rubber, butyl rubber, TPE, flexibilized epoxy, epoxy, amorphous PET, urethane acrylic, acrylic, other fluoroelastomers, other materials of similar qualities, or combinations thereof. By way of nonlimiting example, the desiccant may be selected from porous internal surface area particle of aluminosilicates, aluminophosphosilicates, or similar material. In one embodiment without desiccant, with module perimeter length of about 5 meters, moisture barrier height of 0.5 mm, moisture barrier width of 1 cm, then 0 to 0.25 g/m2 day cm at 50 C and 100% (humidity), is preferable, optionally 0 to 0.1 g/m2 day cm, optionally 0 to 0.01 g/m2 day cm. It should be understood that the moisture barrier 60 may be in the form of a preformed edge tape or it may be a hot melt paste or similar material that is extruded and applied directly to the module 10.

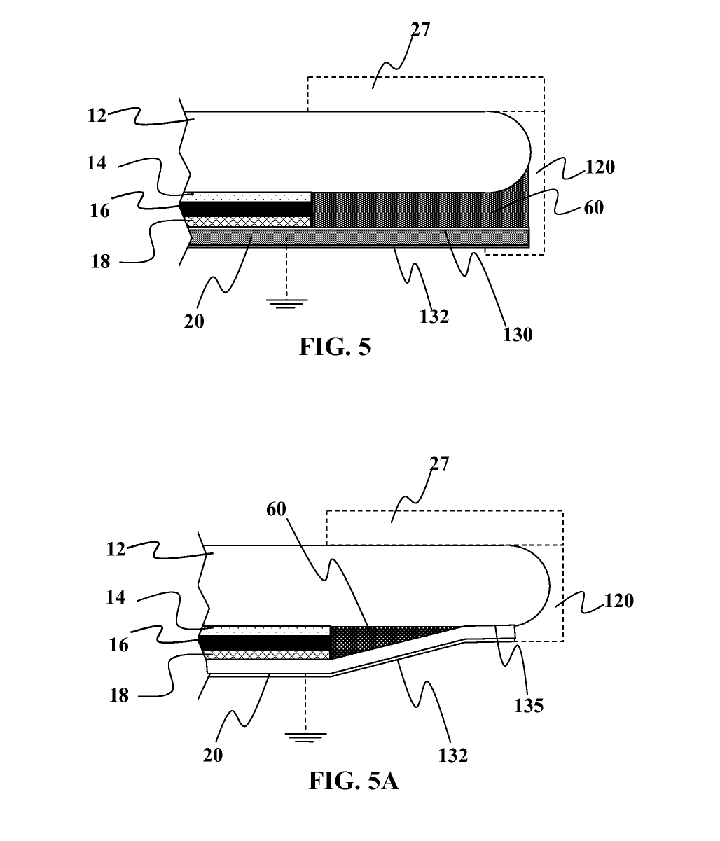

Referring now to FIG. 5 a still further embodiment of the present invention will now be described. FIG. 5 shows that the module back layer 20 may be anodized to create further protective layers 130 and 132 on the module back layer 20. All aluminum generally has a native oxide (aluminum oxide) on the surface and is very thin. The native oxide is typically less than one micron thick, possibly much less than one micron. Anodization can significantly increase the amount of protection provided by an aluminum oxide layer.

In one technique, anodization of module back layer 20 may involve passing the aluminum through a sulfuric acid bath. Electric current is used to drive the reaction forward to make anodization occur quickly. The resulting aluminum oxide from anodization is a durable material since aluminum oxide is the base material for ruby or sapphire. In some embodiments, the hard anodization may be as thick as the foil used for module back layer 20. Depending on the thickness of the anodized layer, substantial electrical withstand may be provided by the anodized layer. For example, a defect-free anodized layer of about 50 microns thick will provide 2000 V electrical withstand. This protection, however, is somewhat unpredictable as it is defect limited. Since the anodized layer is typically defect ridden, simply creating a thicker layer is not enough to guarantee increased voltage withstand. However, it does provide a secondary layer of protection and improved cut resistance.

It should be understood that the protective layers 130 and 132 may be formed on one or both sides of the module back layer 20. The protective layers 130 and 132 may be designed for scratch resistance, cut resistance, and good cosmetics. An anodized layer is also corrosion resistant to solutions such as salt water. It should be understood that various grades and thicknesses of anodization may be adapted for use with module back layer 20. Some embodiments may go with something that is not as hard. Lightweight anodization may provide a protective layer in the thickness of about 10 to about 50 microns. There are also architectural class (1, 2, etc. . . . ) of anodization providing layers in the thickness of about 10 to about 20 microns, optionally 20 to about 50 microns. In addition to thin anodization, some embodiment may have no additional anodization (i.e. just rely on native oxide) or they may include a polymer coating (laminated film or a wet coating that dries). Optionally, some embodiments only have anodization on one side of the module back layer 20, either on the bottom surface or the top surface. Any of the above may be adapted for use with the present invention.

As seen in FIG. 5 the solar cell 16 may include a pottant layer 14 between the cell and top layer 12. A hard spacer layer 18 may be included below the solar cell 16 to provide a minimum spatial separation between the cell and the module back layer 20. This spatial separation is used in part to define the high voltage resistance of the module. The hard spacer layer may be a layer of fiberglass or other woven material. Optionally, the woven material is electrically non-conductive. It should be understood that the hard spacer layer 18 may be infused with a pottant material such as but not limited to that in the pottant layer 14. The thickness of the hard spacer layer may be in the range of about 50 to about 500 microns, optionally 75 to about 300 microns, optionally about 100 to about 250 microns. In one embodiment, the spacer layer 18 is about 200 microns thick. The thickness of spacer layer 18 may be the same thickness as that of pottant layer 14. Optionally, they may be asymmetric with either pottant layer 14 thicker than layer 18 or vice versa.

FIG. 5A shows a still further embodiment of the present invention. Many of the components of the module in FIG. 5 are found in FIG. 5A. However, the FIG. 5A shows a shaped perimeter moisture barrier 60 that presents a smaller cross-section along the outer perimeter of the module and a wider cross-section along an inner perimeter. In this manner the amount of cross-sectional area of moisture barrier 60 exposed to the external environment is minimized while also providing an increased amount of barrier material 60 (due in part to the increase wedge or cross-section) to absorb moisture. Other geometric shapes for the cross-section of the moisture barrier 60 may also be used so long as there is a decrease area along the outer perimeter and a greater area along an inner perimeter to provide more moisture barrier 60 for absorbing liquid. The outer perimeter area 135 of the foil may be bonded by methods such as but not limited to soldered, ultrasonically welded, indium soldered, glued, adhered, or otherwise attached to the glass. Some embodiments may not have area 135 and is only attached to the glass by barrier 60.

FIG. 3 also shows that some embodiment may optionally have additional protective material such as but not limited to metal foil, metal grating, metal grids, plastic layer, plastic grating, plastic grids, polymer gratings, polymer grids, polymer layers, or the like for protective material 27 (shown in phantom). By way of example and not limitation, this material 27 may be included on thin glass layers 12 wherein the glass is about 1 mm or less. Thin glass modules tend to have much higher impact resistance in the center, but significantly poorer impact resistance along the perimeter. Hence, this perimeter protection will significantly improve resistance to glass cracking due to hail. In one nonlimiting example, the material 27 is of sufficient thickness and/or width that the module can withstand hail test of 227±2 g steel ball falling to the surface of module from 100 cm high.

FIG. 4 shows an embodiment wherein additional soft padding or pottant 29 is added below the layer 22. As a nonlimiting example, the layer 29 may be any of a variety of pottant materials such as but not limited to Tefzel®, ethyl vinyl acetate (EVA), polyvinyl butyral (PVB), ionomer, silicone, thermoplastic polyurethane (TPU), thermoplastic elastomer polyolefin (TPO), tetrafluoroethylene hexafluoropropylene vinylidene (THV), fluorinated ethylene-propylene (FEP), saturated rubber, butyl rubber, thermoplastic elastomer (TPE), flexibilized epoxy, epoxy, amorphous polyethylene terephthalate (PET), urethane acrylic, acrylic, other fluoroelastomers, other materials of similar qualities, or combinations thereof. Optionally, some embodiments may have more than two pottant layers. This additional layer 29 may be applied to any of the embodiments disclosed herein.

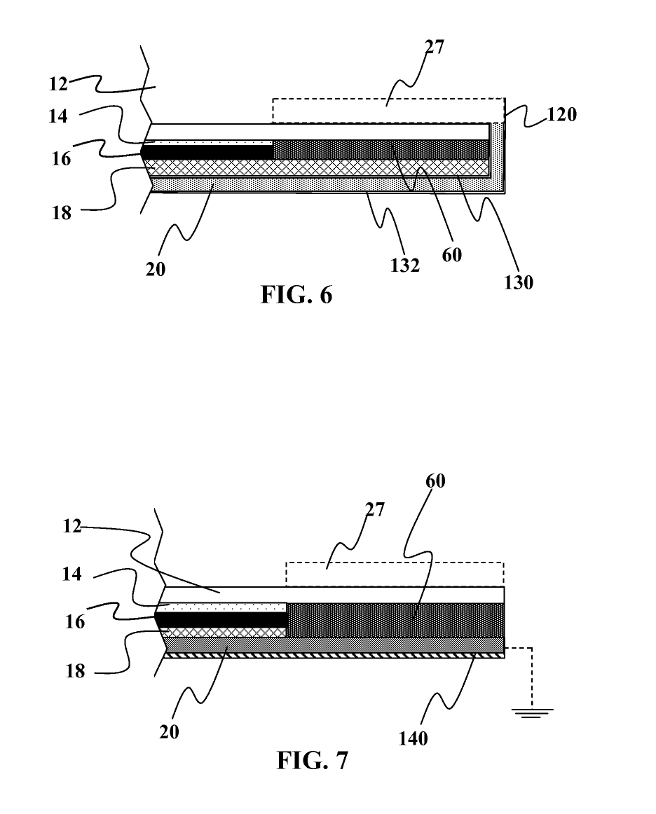

Referring now to FIG. 6 it should be understood that other variations may be incorporated into the module. For example FIG. 6 shows that the module back layer 20 may extend along the sides and/or to the top of the module. The hard spacer layer 18 may extend closer to the edge of the module and be situated partially underneath the moisture barrier 60. It can also be seen in this embodiment that the pottant layer 14 above the cell 16 is thinner than the spacer layer 18 below the cells.

FIG. 7 shows that some backside module layers 20 may be treated to have just one side with an anodized layer 140. The anodized side with layer 140 may be on the underside of the module or it may be on the interior side of the module backside layer 20.

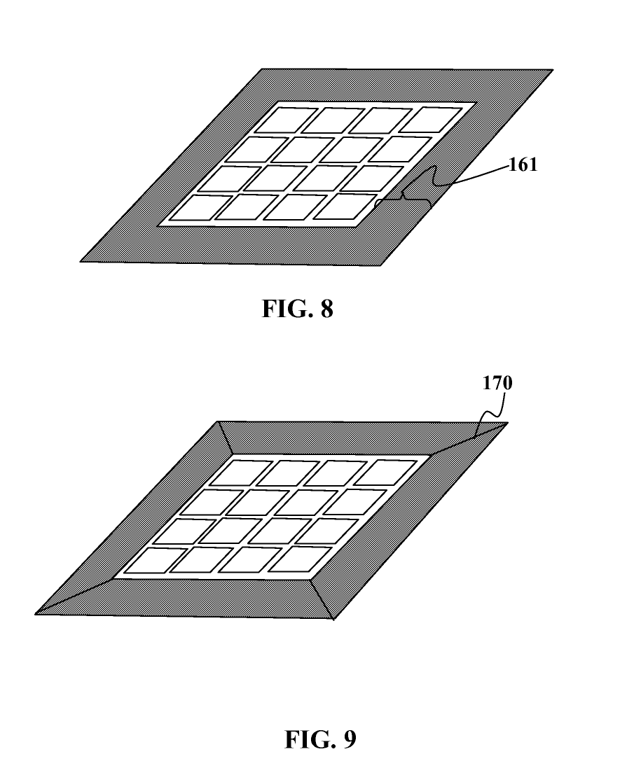

FIG. 8 shows an embodiment wherein the perimeter 161 is of significant width. In one nonlimiting example, the width of the perimeter is at least 3% of the total dimension of the module in that axis. Optionally, the width of the perimeter is at least 5% of the total dimension of the module in that axis. Optionally, the width of the perimeter is at least 7% of the total dimension of the module in that axis. Optionally, the width of the perimeter is at least 10% of the total dimension of the module in that axis. Optionally, the width of the perimeter is at least 15% of the total dimension of the module in that axis. Optionally, the width of the perimeter is at least 20% of the total dimension of the module in that axis. Optionally, the width of the perimeter is at least 25% of the total dimension of the module in that axis. The width of the material along the perimeter is sufficient to deter crack propagation once an impact occurs. Furthermore, it also helps to make the perimeter portion less prone to cracks due the protective, cushioning, and/or strengthening quality associated with the perimeter material.

FIG. 9 shows that some embodiments may use folds of material from the backside of the module. The creases 170 are shown in FIG. 9. There may or may not be overlapping of material at creases 170. Some embodiments may cut the fold over material so that there is no underfolding of material. The surface of the glass may be roughed to improve adhesion. Some embodiments may only have edge protection along portions of the perimeter. Some may only have them on opposing edges. Others may have them on adjacent edges.

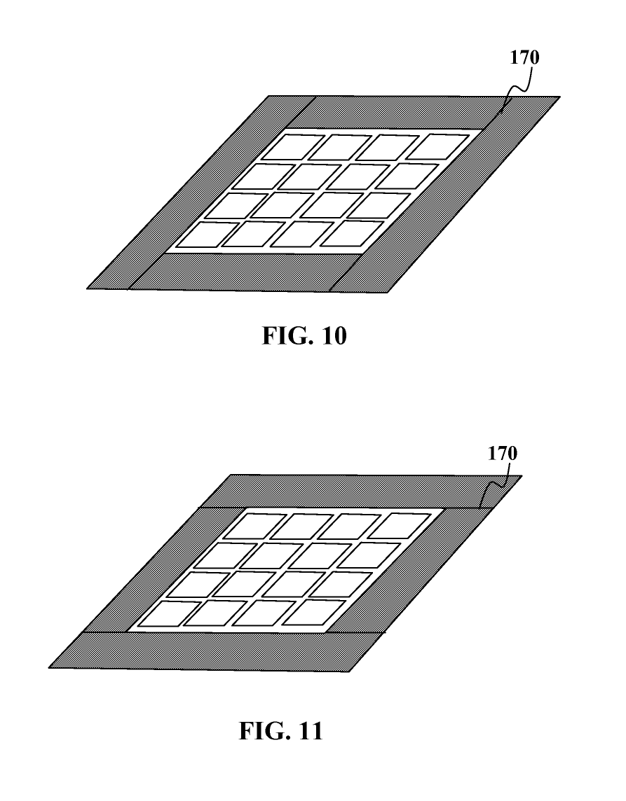

FIGS. 10 and 11 show other embodiments of folding of material from the backside to the front side. Optionally, FIGS. 9-11 may also show additional material placed on top of the module and is not folded to the front from the back. Optionally, some embodiments may have both: additional front material (separate from the back layer) and back layer material folded to the front. As seen in FIGS. 9-11, the cells are typically placed in the central areas not covered by the protective material along the perimeters.

Some embodiments may use a foam or polymer perimeter protection with the thin glass embodiment. The overall thickness of the module may be less than 1 cm with the front side transparent at 1.0 mm or less in thickness. Optionally, the overall thickness of the module may be less than 0.75 cm with the front side transparent at 1.0 mm or less in thickness. Optionally, the overall thickness of the module may be less than 0.5 cm with the front side transparent at 1.0 mm or less in thickness. Other embodiments may use thickness of 2.0 mm or less on the front side.

Optionally, it should be understood that any of the foregoing may also be used with chemically strengthened glass along the perimeter. Optionally, some embodiments use chemically strengthened glass alone, without material 27. By way of example and not limitation, some embodiments strengthen the entire glass surface of the module. Optionally, others oly strengthen the middle. Optionally, others only strengthen the perimeter. Chemically strengthened glass is a type of glass that has increased strength. When broken it still shatters in long pointed splinters similar to float (annealed) glass. For this reason, it is not considered a safety glass and must be laminated if a safety glass is required. Chemically strengthened glass is typically six to eight times the strength of annealed glass.

In one embodiment, the glass is chemically strengthened by submersing the glass in a bath containing a potassium salt (typically potassium nitrate) at 450° C. This causes sodium ions in the glass surface to be replaced by potassium ions from the bath solution. Portions of the glass may or may not be masked so that only select areas (such as the perimeter, or grid patterns) are treated for strengthening.

In this embodiment, these potassium ions are larger than the sodium ions and therefore wedge into the gaps left by the smaller sodium ions when they migrate to the potassium nitrate solution. This replacement of ions causes the surface of the glass to be in a state of compression and the core in compensating tension. The surface compression of chemically strengthened glass may reach up to 690 MPa. Optionally, the surface compression of chemically strengthened glass may reach up to 590 MPa.

There also exists a more advanced two-stage process for making chemically strengthened glass, in which the glass article is first immersed in a sodium nitrate bath at 450° C., which enriches the surface with sodium ions. This leaves more sodium ions on the glass for the immersion in potassium nitrate to replace with potassium ions. In this way, the use of a sodium nitrate bath increases the potential for surface compression in the finished article.

Chemical strengthening results in a strengthening similar to toughened glass, however the process does not use extreme variations of temperature and therefore chemically strengthened glass has little or no bow or warp, optical distortion or strain pattern. This differs from toughened glass, in which slender pieces can often be significantly bowed.

Also unlike toughened glass, chemically strengthened glass may be cut after strengthening, but loses its added strength within the region of approximately 20 mm of the cut. Similarly, when the surface of chemically strengthened glass is deeply scratched, this area loses its additional strength.

The process of chemical strengthening consists of submersing the glass for a given period of time in a potassium nitrate bath at 860° F. (460° C.). During the submersion cycle, the potassium ions are exchanged with the sodium ions. The larger potassium ions “wedge” their way into the voids in the surface of the glass created when the smaller sodium ions migrate to the potassium nitrate solution. This ion exchange locks the surface of the glass in a state of compression and the core in compensating tension. The resulting glass is strengthened.

Chemically strengthened glass is eight times stronger than comparable annealed glass. The entire surface may be chemically strengthened. Optionally, only the perimeter portions are strengthened. The surface compression of chemically strengthened glass may reach up to 100,000 PSI (690 MPa) for a thickness of approx. 0.00125″ (32 μm). Chemically strengthened glass retains its colour and light transmission properties after treatment. Due to its manufacturing process, chemically strengthened glass has little or no bow or warp, optical distortion or strain pattern;

Chemically strengthened glass breaks into sharp fragments like annealed glass. Chemically strengthened glass cannot be used alone as safety glass; it is typically laminated such as in a module or to another transparent layer. Chemically strengthened glass may be cut after tempering, but totally loses its added strength for about 1 inch (254 mm) on either side of the cut. These strips revert to annealed glass. It is preferable to cut and edge the glass before it is chemically strengthened. When the surface chemically strengthened glass is deeply scratched, this area loses its added strength. Such material may be available from Prelco, Inc. of Rivière-du-Loup, Canada or similar manufacturers.

### Thin Glass Module Impact Resistance

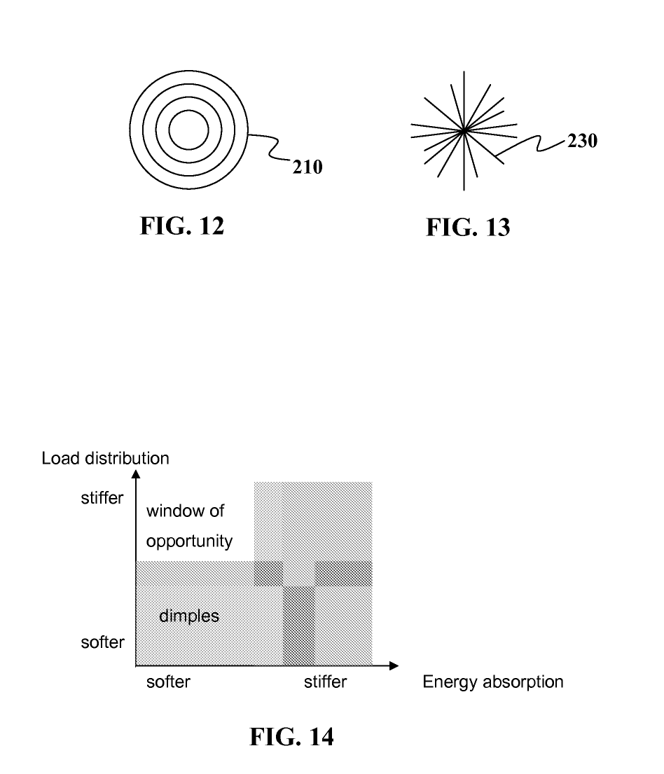

Referring now to FIGS. 12-16, yet another embodiment of the present invention will now be described. In this embodiment, a thin glass-based module is configured to be locally stiff, but sufficiently compliant to survive hail strikes and sufficient to survive tool damage as simulated by steel ball impacts from a predetermined distance such as but not limited to 1 meter. The thin glass layer is particularly fragile, and to improve its impact resistance, is configured to be supported by this stacked backside layer and optionally, with additional front side layers to improve hail resistance.

As seen in FIG. 12, if the support material(s) beneath the thin glass layer is not stiff enough in bending locally, the thin glass of the module will suffer from a dimpling effect, breaking the glass in impact testing with concentric break lines 210 as seen in break pattern of FIG. 12. Thus, the immediate layers beneath the thin glass layer is configured to have some resilience, but not so much that concentric break lines 210 will occur. This may be characterized by an indentation hardness that is sufficient to prevent concentric break lines in the thin glass layer from 227±2 g steel ball dropped from a height of 1 meter. By way of example and not limitation, the indentation hardness of the material is selected to have a durometer (for polymers) of about or Rockwell hardness sufficient to prevent concentric break patterns during the drop test. The desired indentation hardness may be achieved by using one material or multiple materials. Optionally in another embodiment, the desired overall indentation hardness may be achieved by having a multi-ply configuration which in one nonlimiting example, has a soft layer mounted over a harder layer. Optionally, other embodiments may have alternating layers of differing hardness, layers each with a different hardness, a gradation of materials of increasing, decreasing, otherwise varying hardness, or some combination of the foregoing.

Referring now to FIG. 13, if the thin glass support material is too stiff overall, however, the energy of the impact is absorbed (i.e. slowing down the steel ball) by the thin glass rather than the support and this results in radial break lines 230 as show in the break pattern B of FIG. 13 in the thin glass. The rebound hardness or dynamic hardness of the material is such that the impact of the steel ball is absorbed without dimple fracturing the material locally while the entire support flexes at a macro-level to absorb the impact of the steel ball. This flexing may be achieved through properties of the materials beneath the thin glass layer, through the mounting structures used to support the thin-glass module (allowing the module to flex), or both. By way of nonlimiting example, the module may be mounted using the one-degree of freedom module mounts such as those described in U.S. Provisional Application Ser. No. 61/060,793 filed Jun. 11, 2008.

As seen in FIG. 14, the present embodiment of the thin glass module embodies a sweet spot of support stiffness that is configured to be stiff enough locally and compliant enough overall to avoid both break cases.

Only if considering the interaction between the various layers and the mounting scheme at the same time, the system can be configured for lowest cost. By way of nonlimiting example, a soft dampening layer (or a void or soft clamping) behind the stiff first layer will absorb the impact energy, but the first stiff layer is still desired to distribute the impact forces. Optionally, a thin soft layer in front of the glass can also serve as the energy absorption layer; it does not have to be a layer behind the glass.

In one nonlimiting example, the thin glass module comprises of variety of layers which from top to bottom may include: a) an optional layer for impact area spreading (optionally thinner, thicker, or the same as the thin glass layer); b) a borosilicate/thin glass layer that is a moisture barrier; c) transparent encapsulant; d) cell; e) adhesive+metal laminate moisture barrier; f) adhesive, g) a stiffening layer such as but not limited to Fiber Reinforced Plastic (glass fiber reinforced vinylester). By way of example, the stiffening layer g) is typically of greater thickness than the other layers above it and provides rebound hardness or dynamic hardness to prevent radial cracking of the thin glass layer. Optionally the stiffening layer g) may be the same thickness or thinner than the thin glass layer. Optionally, the stiffening layer g) may be surface treated to harden it or to soften it to minimize the risk of radial break lines.

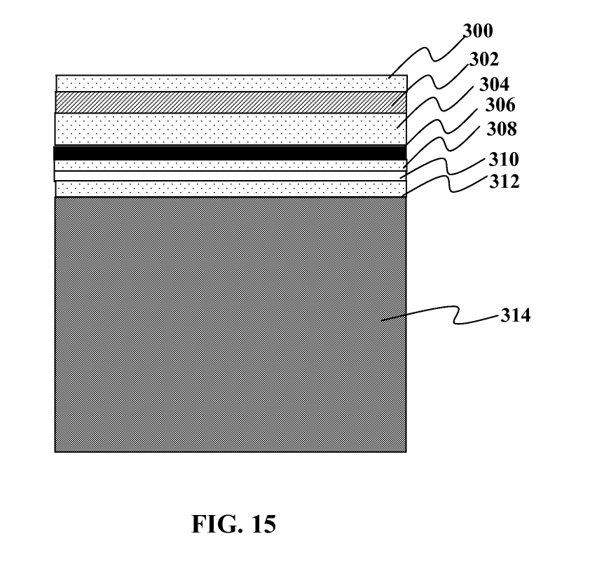

Referring now to FIG. 15 in one nonlimiting example, the thin glass module comprises of a) a 200 μm TPO layer 300 for impact area spreading, b) a 250 μm borosilicate/thin glass layer 302 that is a moisture barrier; c) 400 μm TPO/transparent encapsulant 304; d) cell 306; e) 200 μm TPO 308; f) 100 μm of aluminum 310/which acts as a moisture barrier; g) 200 μm TPO 312; and h) 3 mm Fiber Reinforced Plastic (glass fiber reinforced vinylester) 314. In this embodiment, there is an impact area spreading layer above and below the thin glass layer. However, maximum deflection of any ball strikes in this embodiment is limited by the use of a fiber reinforced plastic in support layer 314 this is harder than the impact spreading layer. Optionally, other support layers made of different materials may also be used if they are similar in hardness to that of the fiber reinforced layer. Optionally, some support layers may be harder or softer. Optionally, the support layer 314 may itself by surface treated to provide the desired surface hardness. The ratios of material thickness may be as set forth above or varied to improve performance. In many embodiments, it is desirable to have the from impact area spreading layer 300 and a back side support layer 314 of significantly greater thickness. The embodiments may also be adapted for use with the foil wrapping shown in the prior embodiments of FIGS. 1 through 11 for moisture barrier protection. By way of nonlimiting example, the foil wrap may include the support layer 314 with it or be mounted on the support layer 314.

As seen in this example of FIG. 15, the front side impact spreading layer 300 may be thinner than the layer 304 beneath the thin glass layer. Optionally, the front side impact spreading layer 300 may be the same thickness as the layer 304 beneath the thin glass layer. Optionally, the front side impact spreading layer 300 may be thicker than the layer 304 beneath the thin glass layer. The layers 300 and 304 may be of the same material or different material. Optionally, the thin glass layer may be 1.0 mm or less in thickness. Optionally, the thin glass layer may be 0.9 mm or less in thickness. Optionally, the thin glass layer may be 0.8 mm or less in thickness. Optionally, the thin glass layer may be 0.7 mm or less in thickness. Optionally, the thin glass layer may be 0.6 mm or less in thickness. Optionally, the thin glass layer may be 0.5 mm or less in thickness. Optionally, the thin glass layer may be 0.4 mm or less in thickness. Optionally, the thin glass layer may be 0.3 mm or less in thickness. Optionally, the thin glass layer may be 0.2 mm or less in thickness. Optionally, the thin glass layer may be 0.1 mm or less in thickness. Optionally, the thin glass layer may be 0.05 mm or less in thickness. In many embodiments, the glass is in the thickness range of about 0.5 mm to about 0.05 mm. Glass thicknesses may optionally be in the 0.25 mm to 0.15 mm range. The thin glass is not limited to borosilicate glass and other glass types such as but not limited to soda lime glass, annealed soda lime glass, tempered soda lime glass, float glass, low-e glass, or the like may also be used.

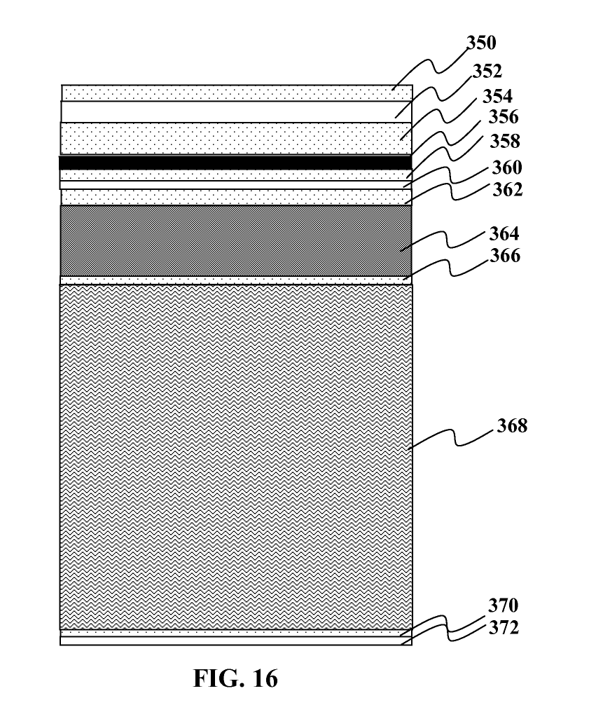

Referring now to FIG. 16 in another nonlimiting example, the thin glass module comprises of a) 200 μm TPO impact area spreading layer 350; b) 200 μam borosilicate/thin glass for transparent moisture barrier 352; c) 400 μm TPO/as transparent encapsulant 354; c) cell 356; d) 200 μm TPO 358; e) 100 μm of aluminum/as moisture barrier 360; f) 200 μm TPO 362; g) 870 μm Fiber Reinforced Plastic (glass fiber reinforced vinylester)/as locally stiff backing 364 to limit borosilicate deflection; h) 100 μm TPO 366; i) 12 mm cardboard honeycomb 368/as spacer to increase impact of aluminum skin on stiffness; j) 100 μm TPO 370; k) 100 μm Aluminum/as a stiffening layer 372 to make the module easier to limit large scale deflection.

In yet another embodiment, the thin glass module comprises of a) 100 μm to 1000 μm transparent impact area spreading layer; b) a 100 μm to 750 μm thin glass transparent moisture barrier; c) 50 μm to 600 μm spreading layer/as transparent encapsulant; c) cell; d) 100 μm to 500 μm adhesive; e) 100 to 300 μm of moisture barrier; f) 100 to 300 μm of adhesive; g) about 1 mm to about 20 mm of homogenous or multi-ply support layer.

In yet another embodiment, the thin glass module comprises of a) 100 μm to 1000 μm transparent impact area spreading layer; b) a 50 μm to 250 μm thin glass transparent moisture barrier; c) 50 μm to 800 μm spreading layer/as transparent encapsulant; c) cell (about 300 μm; d) 100 μm to 500 μm adhesive; e) moisture barrier; f) adhesive; g) about 1 mm to about 20 mm of homogenous or multi-ply support layer.

In some embodiments, it is particularly desirable to have a front side transparent impact area spreading layer above the thin glass layer. By way of nonlimiting example, such a layer may be 50 μm to 1000 μm transparent impact area spreading layer. Optionally, in other embodiments, it is desirable to control the distance between the thin glass and the bottom support layer such as layer 314 by controlling cell thickness and encapsulant and any other layers therebetween. By way of nonlimiting example, such a distance between underside of the thin glass and the bottom support layer may be less than about 2000 μm in one embodiment. By way of nonlimiting example, such a distance between underside of the thin glass and the bottom support layer may be less than about 1500 μm in one embodiment. By way of nonlimiting example, such a distance between underside of the thin glass and the bottom support layer may be less than about 1000 μm in one embodiment. By way of nonlimiting example, such a distance between underside of the thin glass and the bottom support layer may be less than about 900 μm in one embodiment. By way of nonlimiting example, such a distance between underside of the thin glass and the bottom support layer may be less than about 800 μm in one embodiment. By way of nonlimiting example, such a distance between underside of the thin glass and the bottom support layer may be less than about 700 μm in one embodiment. By way of nonlimiting example, such a distance between underside of the thin glass and the bottom support layer may be less than about 600 μm in one embodiment. By way of nonlimiting example, such a distance between underside of the thin glass and the bottom support layer may be less than about 500 μm in one embodiment. By way of nonlimiting example, such a distance between underside of the thin glass and the bottom support layer may be less than about 400 μm in one embodiment. By way of nonlimiting example, such a distance between underside of the thin glass and the bottom support layer may be less than about 300 μm in one embodiment.

It should be understood that the weight of these thin glass modules are significantly less than those of traditional module design. For example, the present modules would weight about 10% to about 50% of the weight of a traditional glass-glass module (3.2 mm glass on each side) of comparable size. By way of nonlimiting example, the embodiments of the present invention would weight between 3 kg and 15 kg for a module with a 2 meter by 1 meter size.

Furthermore, it should be understood that in addition to being able to survive hail strikes and steel ball strikes, the same panel configuration would also need to be able to survive certain load (both from the front or the rear of the panel). It should be understood that glass breaks in tension. If the thin glass layer is the top or close to the top layer, the snow load or wind load from the top is generally not an issue since in those conditions, the glass will most likely be in compression. As seen in FIG. 16, the neutral phase or neutral axis 250 of the stack is into the support structure and therefore, the glass is in compression.

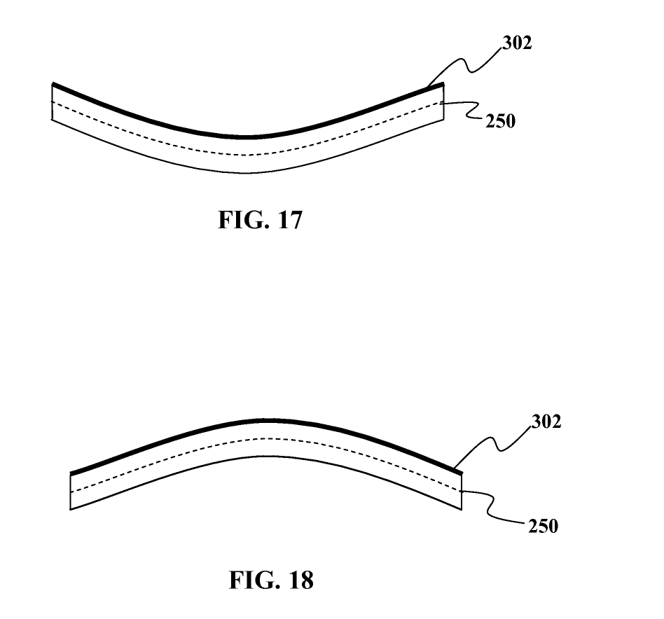

Referring to FIG. 17, the case that is more critical is the wind load in the other direction (upward, from the backside, or the side opposite that which the thin glass is mounted) and bending the panel up. Then the entire stack is bent in the other direction (convex) and then the thin glass 302 is in tension, creating increased likelihood of breakage since the glass is on the side of the neutral phase that is in tension.

Thus, the thicker the support layer becomes, the further the thin glass on top is away from the neutral phase during reverse wind load. There is a linear correlation here; the further away the layer is from the neutral phase, the more tension there will be in that thin glass layer. There is a desire to keep the support layer as thin as possible, as thicker layers will amplify the module in tension in reverse wind load.

However, at the same time, the support layer should provide enough stiff support to prevent dimpling in the FIG. 12. The material should thus be a certain stiffness, but does not exceed a certain thickness. Some materials that can be used include random fiber with epoxy (PET) filled, woven fiber, steel, other metal layers, etc. . . . . If the material gets too stiff, the neutral phase is calculated from the moduli of each material. By its e-modulus of a stiffer material, it will pull the neutral phase to itself. Therefore one desires something that does not unnecessarily pull the neutral phase towards it, but at the same time, is sufficiently stiff to prevent dimpling fracture lines but not so stiff as to create concentric fracture lines. For example, some successful embodiments include woven glass fiber with epoxy or other similar stiffness filler. In this nonlimiting example, this is relatively thin (3 mils or 4 mils) (0.75 or 1 mm) in thickness but is still stiff enough to pass both the metal ball drop test and the 2400 pa reverse static wind load test. Such a material has a Flexural Modulus of Elasticity (PSI) 2,700,000. Flexural strength may be about 100,000 lbf/in² Lengthwise. Optionally, it has a 75,000 lbf/in² crosswise. The material has a Rockwell Hardness (M scale) of about 110. It has a Dimensional Stability, E-2/150 of <0.04% Warp/fill and/or <1.00% Bow/Twist.

Optionally, the material has Compressive Strength (PSI) 60,000, Flexural Strength (PSI) 55,000; Impact Strength, IZOD (Notched) (FT-LBS PER INCH OF NOTCH) 7; Flexural Modulus of Elasticity (PSI) 2,700,000. Arc Resistance (SECONDS) 80. Other embodiments may have an arc resistance as high as 125 s.

Optionally, the material has Flexural Strength (PSI) between about 60,000 and 75,000 PSI. Optionally, the material has a Flexural Modulus of Elasticity (PSI) between about 2,650,000 to about 2,750,000. Optionally, the material has a Flexural Modulus of Elasticity (PSI) between about 2,600,000 to about 2,800,000. Optionally, the material has a Flexural Modulus of Elasticity (PSI) between about 2,500,000 to about 2,900,000. Optionally, the material has a Flexural Modulus of Elasticity (PSI) between about 2,400,000 to about 3,000,000.

Modulus in Bending is a ratio of maximum fiber stress to maximum strain, within elastic limit of Stress-Strain Diagram obtained in flexure test. Alternate term is flexural modulus of elasticity.

Optionally, the deflection resulting from wind load is what matters. There is a minimum radius that the panel can make before it breaks. This can also be minimized by the mounting technique used. Thus if the solar module make less of a radius during reverse loading, then it is fine again. Optionally, the system may use a tension mounting system such as the described in PCT application PCT/US09/48731 filed Jun. 25, 2009 and fully incorporated by herein by reference for all purposes. This tension mounting may be used minimize the radius of curvature seen by the thin glass 302 and minimize putting the panel into tension. The radius may also be minimized by mechanical stiffeners such as but not limited to reinforcement bars on the panel or on the module mounts that will not slide and put the panel into tension and not bend.

Typically, the back support is a stiff material, but not too thick. At some point, the back becomes so thick, then it does not bend. These embodiments may also be used so long as there is no bending. Thus, even if the thin glass is located further from the neutral phase, if there is no bending or substantially no bending (such as at least 90% nonbending), then it does not matter the distance from the neutral phase due to the lack of bending. Thus, some embodiments such as random fiber PET fiberboard is not stiff enough to survive hail test and steel ball test. However, by making these layers much thicker such as in the area of about ½ inch or even more, they become sufficiently stiff. Particle board is stiff enough.

Optionally, some embodiments may use a hybrid laminate wherein the layer 312 is an adhesive layer and an impact stiffening layer. If layer 312 is stiff enough that there is no dimpling during impact, then Styrofoam which is otherwise too soft, can be used for 314 to address overall stiffness in the reverse wind load condition.

In yet another embodiment, the impact spreading layer may be a disposable, removable adhesive layer. This removable layer is provided so that the module can withstand the metal ball impacts that are used to simulate the dropping of a tool on the panel during installation or transport. Once the module is fully installed at the worksite, the layer 300 may be pealed off. This may be desirable so that the layer 300 does not need to be designed to have the some 20 to 25 lifetime operating requirements of the other layers in the module stack. Those other layers may need to be able to remain transparent, non-yellowed or the like for the 20 to 25 year lifetime. By removing the layer 300 prior to operation, a different type of material may be used. In some embodiments, this material may be a non-transparent layer. It may be opaque so that no electricity is generated by the module prior to completion of installation. This reduces the risk of electric shock to humans or others during installation. The layer 300 may also act to contain any glass shards which may be created if the glass is broken during transport or installation.

The above embodiments are configured for hail test to survive without panel breaking Steel ball test has a different requirement, such that afterwards, there are no electrical contacts exposed. Panel may be broken but not electrical contacts are exposed. The present embodiments, however, can survive the steel ball test without damage to panel.

Furthermore, there is an interplay with adhesive layer thickness and the support layer 314. If TPO, other adhesive, or encapsulant layer is too thick, then it gets too soft and the glass will get dimpling fractures. The thinner the TPO is usually better if there is enough softness in the support 314 under it. In one embodiment, TPO of 1000 microns is likely too much. Optionally, in other embodiments, 1500 microns of encapsulant such as EVA is too much. Optionally, in other embodiments, 1000 microns of encapsulant such as EVA is too much.

With regards to the thin glass 302, the thickness in one embodiment may be in the range from about 0.15 mm to about 0.30 mm. Optionally, some embodiments may use 0.2 mm to 0.15 mm thick glass. Optionally, some embodiments may use 0.2 mm to 0.17 mm thick glass. Glass as thin as 0.05 mm is available and may be used in some embodiments. Thicker glass is not necessarily better as thicker tends to introduce tension in the material during reverse wind loads. In one nonlimiting example, the overall module size is 540 mm by 1667 mm. Optionally, the module is between about 400 to 600 mm in one dimension and about 1500 to 2000 mm in the other dimension. These thin glass modules are able to provide significant weight advantages. For example, a glass-glass module is about 15 kg per square meter. A glass-foil module is about 10 kg per sq m. A thin-glass module is in the area of about 5 kg per sq m. All of the foregoing use the same cells that may be thin-film on metal foil or metallized polymer such as described in U.S. patent application Ser. No. 11/278,645 filed Apr. 4, 2006 and fully incorporated herein by reference for all purposes.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, although glass is the layer most often described as the top layer for the module, it should be understood that other material may be used and some multi-laminate materials may be used in place of or in combination with the glass. Some embodiments may use flexible top layers or coversheets. By way of nonlimiting example, the backsheet is not limited to rigid modules and may be adapted for use with flexible solar modules and flexible photovoltaic building materials. Embodiments of the present invention may be adapted for use with superstrate or substrate designs. Embodiments of the present invention may be used with mounting apparatus such as that shown or suggested in U.S. Application Ser. No. 61060793 filed Jun. 11, 2008 and fully incorporated herein by reference for all purposes. Some embodiments may use materials such as but not limited to Norplex NP130HF Glass Fabric, Norplex NP502 Glass Fabric, or the like.

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited. For example, U.S. Provisional Patent Application No. 61/088,702 filed Aug. 13, 2008 and U.S. patent application. Ser. No. 11/243,522 filed Oct. 3, 2005 are fully incorporated herein by reference for all purposes.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A photovoltaic module comprising:
a thin glass layer with a thickness of about 0.5 mm or less;
a support layer beneath the thin glass layer that has sufficient compliance to prevent radial cracking of the thin glass layer and has sufficient indentation hardness to prevent concentric cracking of the thin glass layer from 227 g metal ball strikes dropped from a height of 1 m; and
a plurality of solar cells are between the thin glass layer and the support layer.

2. The module of claim 1 wherein the thin glass layer has a thickness of 0.40 mm or less.

3. The module of claim 1 wherein the thin glass layer has a thickness of 0.30 mm or less.

4. The module of claim 1 wherein the thin glass layer has a thickness of 0.25 mm or less.

5. The module of claim 1 wherein the thin glass layer has a thickness of 0.17 mm or less.

6. The module of claim 1 wherein the thin glass layer has a thickness of 0.15 mm or less.

7. The module of claim 1 wherein the support layer comprises a fiber reinforced plastic.

8. The module of claim 1 wherein the support layer comprises an epoxy based woven fiber material.

9. The module of claim 1 wherein the support layer has a thickness that provides a bending radius less than a breaking radius for a reverse static load of 2400 pa.

10. The module of claim 1 wherein the support layer has a thickness between about 700 microns to about 1000 microns.

11. The module of claim 1 wherein the support layer has a thickness between about 600 microns to about 1100 microns.

12. The module of claim 1 wherein the support layer has a thickness between about 750 microns.

13. The module of claim 1 wherein the support layer has a Flexural Modulus of Elasticity (PSI) between about 2,650,000 to about 2,750,000.

14. The module of claim 1 wherein the support layer has a Flexural Modulus of Elasticity (PSI) between about 2,690,000 to about 2,710,000.

15. The module of claim 1 wherein the support layer has a Flexural Modulus of Elasticity (PSI) between about 2,650,000 to about 2,750,000 with a thickness between about 700 microns to about 1100 microns.

16. The module of claim 1 wherein the support layer has a Flexural Modulus of Elasticity (PSI) between about 2,700,000 with a thickness between about 700 microns to about 1000 microns.

17. The module of claim 1 wherein the support layer comprises of a woven glass fiber material with epoxy.

18. The module of claim 1 further comprising an impact spreading layer above the thin glass layer.

19. The module of claim 18 wherein the impact spreading layer comprises of an opaque polymer material removably adhered to the thin glass layer.

20. The module of claim 1 wherein the support layer comprises a mechanically stable glass cloth epoxy resin, laminated under high pressure
